(19) United States
(12) Patent Application Publication
(10) Pub. No.: US 2007/0220743 A1
(43) Pub. Date: Sep. 27, 2007

(54) ELECTRIC CURRENT BONDING APPARATUS AND ELECTRIC CURRENT BONDING METHOD

(76) Inventors: Takeshi Tsukamoto, Hitachinaka (JP); Tadashi Kasuya, Hitachi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/626,861

(22) Filed: Jan. 25, 2007

(30) Foreign Application Priority Data
Mar. 27, 2006 (JP) 2006-085524

(51) Int. Cl. H05K 3/20

(52) U.S. Cl. 29/831; 29/745

(57) ABSTRACT

An electric current bonding apparatus, comprising: a plurality of metallic members 101, 102 through which electric current is capable of flowing; a pressurizing unit 2a1, 2a2, 2b for applying pressing forces to the plurality of metallic members 101, 102 so as to press the metallic members against each other; a plurality of paired electrodes 12a, 12b disposed on the plurality of metallic members 101, 102 to heat the metallic members by use of resistance heat generated by a flow of electric current; a power supply 6a, 6b for supplying electric current to the plurality of paired electrodes; and an energizing controller 5 for supplying electric current from the power supply to the plurality of electrodes by making a switchover to an electrode pair across to supply the electric current.

### CLAIM OF PRIORITY

the present application claims priority from Japanese application serial No. 2006-085524, filed on Mar. 27, 2006, the contents of which is hereby incorporated by reference into this application.

### BACKGROUND OF THE INVENTION

1. Field of Technology

The present invention relates to an electric current bonding apparatus and an electric current bonding method which are mainly used for metallic materials, with poor weldability, of the same type and different types.

2. Prior Art

In the resistance welding method by which metallic materials are bonded, current flows in the metallic members to be bonded under pressure, and Joule heat generated by the electric resistance on the bonding interface and the internal electric resistance of the metallic materials is used to heat and bond the metallic materials. The resistance welding method is advantageous in that energy efficiency is high and bonding time is short because a temperature rise and material deformation occur, centered around a bonding portion, so the resistance welding method is widely used in the automobile industry and other industrial fields.

Since the resistance welding method is a technique in which a high current density is used to raise heat rapidly, however, heating may change depending on the bonding interface and the state of the contact between the metallic members and electrodes through which electric current flows, resulting in variations in welding quality. In particular, a uniformly welded portion cannot be obtained easily if the bonding area of the metallic members is large.

In most cases, the metallic materials are partially fused at the bonding portion so as to bond the metallic materials. If the weldability of the metallic materials is poor, for example, if cracks or brittle compounds are generated after fusion or solidification, superior quality cannot be obtained.

There are electric current sinter bonding methods that solve the above problems by supplying DC current continuously or supplying pulsed electric current, as described in Japanese Patent Application Laid-open Publication No. 3548509, Japanese Patent Application Laid-open Publication No. 2003-112264, Japanese Patent Application Laid-open Publication No. 2005-21946, and Japanese Patent Application Laid-open Publication No. 2005-262244. These electric current sinter bonding methods are called a continuous electric current bonding method, a pulsed electric current sinter bonding method, a pulsed electric current bonding method, a sparked plasma sinter bonding method, and a sparked plasma bonding method.

In these bonding methods, members to be bonded are placed between electrodes, which are oppositely disposed, in such a way that their faying surfaces face each other. Pressure is applied to the faying surfaces by a pressurizing mechanism through the electrodes, and then continuous current, pulsed current, or current obtained by combining them is passed across the electrodes so as to generate resistance heat around the bonding interface.

The current density at this time is a fraction of a little more than ten to several tens as compared to resistance welding. Heating is performed within a solid state temperature region, the lower limit of which is equal to or lower than the melting temperatures of the materials to be bonded. The materials are then softened and deformed, so bonding is performed by a tight contact on the bonding interface and a solid state diffusion phenomenon.

The heating rate at the bonding part is lower than in the resistance welding method, so minute changes occur on the faying surface as the temperature rises, increasing the tightness of the contact on the bonding interface. A uniform bonding part can be thereby obtained easily even if the bonding area is large. Deformation due to bonding is small because the materials to be bonded do not melt. Accordingly, the electric current sinter bonding methods can also be applied to materials with poor weldability from which superior quality cannot be obtained easily in fusion welding.

The bonding methods in which the contact on the bonding interface and the solid state diffusion phenomenon are used include a hot-pressure welding method and a solid-state diffusion bonding method. In these methods, however, members to be bonded need to be heated entirely and uniformly in a heat treatment furnace, taking a long time from several hours to tens of hours to bond the members. Large bonding deformation also occurs because the entire members are deformed similarly. In the continuous electric current bonding method, local heating is performed, shortening the time taken for bonding and suppressing the bonding deformation, as compared the above methods.

Patent Document 1: Japanese Patent Application Laid-open Publication No. 3548509

Patent Document 2: Japanese Patent Application Laid-open Publication No. 2003-112264

Patent Document 3: Japanese Patent Application Laid-open Publication No. 2005-21946

Patent Document 4: Japanese Patent Application Laid-open Publication No. 2005-262244

### SUMMARY OF THE INVENTION

When the metallic members to be bonded have parts that differ in thickness, however, the conventional electric current sinter bonding methods described in Patent Documents 1 to 4 may cause different heating efficiencies between a thick part and a thin part; the temperature of the thick part is low and the temperature of the thin part is high.

This is problematic in that even when the faying surface of the thin part reaches its target bonding temperature, heating on the faying surface of the thick part is insufficient, resulting in an insufficient boding strength or a failure to bond the metallic members.

Conversely, if the faying surface of the thick part is heated to its target bonding temperature, the temperature of the thin part exceeds its target bonding temperature, causing crystal grains to be coarse or to be melted. As a result, the material properties may be deteriorated.

Even when the metallic members to be bonded have the same thickness, if the faying surfaces of the metallic members are large, a temperature gradient occurs on the faying surfaces between their central part and outer periphery, causing a problem as described above. In the conventional electric current bonding methods in which a pair of electrodes are used to carry current, it is difficult to adjust the temperature gradient caused on the faying surfaces of the metallic members due to their shapes and sizes.

The object of the present invention is to provide an electric current bonding apparatus and an electric current bonding method that suppress a difference in temperature on the faying surfaces of the metallic members to be mutually bonded by electric current bonding so as to enable uniform electric current bonding between the metallic members independently of their shapes and sizes.

An electric current bonding apparatus according to the present invention comprises a plurality of metallic members through which electric current is capable of flowing, a pressurizing unit for applying pressing forces to the plurality of metallic members so as to press the metallic members against each other,

a plurality of paired electrodes disposed on the plurality of metallic members to heat the metallic members by use of resistance heat generated by a flow of electric current, a power supply for supplying electric current to the plurality of paired electrodes, and an energizing controller for supplying electric current from the power supply to the plurality of electrodes by making a switchover to an electrode pair across which to supply the electric current.

Another electric current bonding apparatus according to the present invention comprises a plurality of metallic members through which electric current is capable of flowing, a pressurizing unit for applying pressing forces to the plurality of metallic members so as to press the metallic members against each other, a plurality of paired electrodes disposed on the plurality of metallic members to heat the metallic members by use of resistance heat generated by a flow of electric current, a plurality of power supplies for supplying electric current to the plurality of paired electrodes through a plurality of energizing paths, an energizing switching unit for making a switchover among the plurality of energizing paths through which electric current is supplied to the plurality of paired electrodes, and an energizing controller for controlling the energizing path switchover by the energizing switching unit so that current is supplied from the power supply to the plurality of paired electrodes.

An electric current bonding method according to the present invention comprising steps of; applying external pressing forces are applied to a plurality of metallic members through which electric current is capable of flowing so as to press the metallic members against each other, supplying electric current across the plurality of metallic members under the pressure, and heating and bonding the metallic members by use of resistance heat generated by the current supply, wherein: disposing a plurality of paired electrodes to supply electric current between the plurality of metallic members, and selecting an electrode pair to supply electric current from among the plurality of paired electrodes and supplying the electric current across the selected electrode pair so that the plurality of metallic members are heated within a desired temperature region and bonded.

According to the present invention, an electric current bonding apparatus and an electric current bonding method are implemented that enable uniform electric current bonding between metallic materials by suppressing a difference in temperature on the faying surfaces of the metallic members to be mutually bonded by use of current, independently of the shapes and sizes of the metallic members to be bonded.

### BRIEF DESCRIPTION OF THE DRAWINGS

FIG. 1 shows the general structure of an electric current bonding apparatus in an embodiment of the present invention.

FIG. 2 shows current waveforms representing an example of amounts of current supplied by the electric current bonding apparatus in the embodiment of the present invention shown in FIG. 1.

FIG. 3 shows the general structure of an electric current bonding apparatus in another embodiment of the present invention.

FIG. 4 shows current waveforms representing an example of amounts of current supplied by the electric current bonding apparatus in the embodiment of the present invention shown in FIG. 3.

FIG. 5 shows the general structure of an electric current bonding apparatus in other embodiment of the present invention.

FIG. 6 is a plan view of the electric current bonding apparatus in the other embodiment of the present invention shown in FIG. 5.

FIG. 7A shows current waveforms representing an example of amounts of current supplied by the electric current bonding apparatus in the other embodiment of the present invention shown in FIG. 5.

FIG. 7B shows current waveforms representing another example of amounts of current supplied by the electric current bonding apparatus in the other embodiment of the present invention shown in FIG. 5.

### DETAILED DESCRIPTION OF THE INVENTION

An electric current bonding apparatus and an electric current bonding method as an embodiment of the present invention will now be described with reference to the drawings.

### Embodiment 1

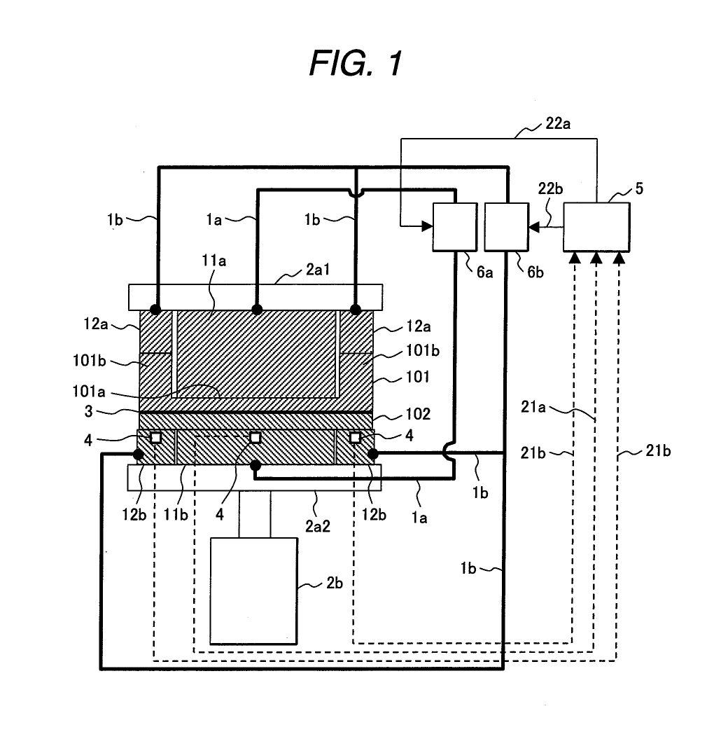

FIG. 1 shows the general structure of an electric current bonding apparatus in a first embodiment of the present invention, which includes metallic members to be bonded, electrodes, a power supply, a pressurizing mechanism, and an energizing controller when two metallic members are bonded. The structures of the metallic members to be bonded and electrodes are indicated as cross-sectional views. In this embodiment, alloy tool steel SKD61 is used as an example of the metallic member to be bonded.

In FIG. 1, a metallic member to be bonded disposed as the upper metallic member made of the metallic material SKD61 is a differential thickness member 101 that is a disk-like and has a concave cross section. The upper metallic member to be bonded comprises a thin central part 101a and a thick end 101b formed on the outer periphery of the central part 101a. The other metallic member disposed as the bottom metallic member is a disk-like plate member 102 that has a uniform thickness and is bonded to the differential thickness member 101.

The differential thickness member 101 and the plate member 102 are disposed in such a way that faying surfaces 3, which are their opposite surfaces, are brought into contact with each other. When current is supplied by the electric current bonding apparatus under pressure, resistance heat is generated on the contact surfaces of the differential thickness member 101 and the plate member 102 and inside the material thereof, thereby heating and mutually bonding the members.

Specifically, an electrode A 11a is provided on the thin central part 101a, which forms a concave bottom of the disk-like differential thickness member 101, and a plurality of electrodes B 12a are provided on the thick end 101b of the differential thickness member 101.

When electric current flows, a voltage is applied from a power supply 6a to the electrode A 11a disposed on the differential thickness member 101 through an energizing path 1a, and a voltage is applied from a power supply 6b to each of the plurality of electrodes B 12a through an energizing path 1b.

An electrode A 11b is also provided on the back of the disk-like plate member 102, having a uniform thickness, at the center, and a plurality of electrodes B 12b are also provided on the back of the peripheral end of the plate member 102.

When electric current flows, a voltage is applied from the power supply 6a to the electrode A 11b disposed on the back of the plate member 102 through another energizing path 1a, and a voltage is applied from the power supply 6b to each of the plurality of electrodes B 12b through another energizing path 1b.

The pressurizing mechanism for pressing both the differential thickness member 101 and the plate member 102 to be mutually bonded comprises a pressing tool 2a1 for pressing the differential thickness member 101 from above, a pressing tool 2a2 for pressing the plate member 102 from below, and a pressurizing means 2b, such as a hydraulic cylinder, for supplying pressing forces to both the pressing tool 2a1 and pressing tool 2a2.

The electrode A 11b disposed on the back of the plate member 102 at the center and the plurality of electrodes B 12b disposed on the back of the end of the plate member 102 are each provided with a temperature detector 4. A detected temperature signal 21a and detected temperature signals 21b, which are detected by the temperature detectors 4 from the electrode A 11b and the plurality of electrodes B 12b, respectively, are input to the energizing controller 5.

The energizing controller 5 calculates the values of currents to be respectively supplied from the power supplies 6a and 6b to the electrodes A 11a, 11b and the electrodes B 12a, 12b as well as their current supplying times, so that the detected temperatures 21a, 21b each fall within a target temperature region of temperature settings, according to predetermined temperature settings necessary for electric current bonding of the metallic members to be bonded, a temperature setting being input in advance for each metallic material to be bonded, as well as the detected temperature signal 21a and detected temperature signals 21b, which are detected by the temperature detectors 4 from the electrode A 11b and the plurality of electrodes B 12b, respectively, and then input.

Control signals 22a and 22b commanding the amounts, calculated by the energizing controller 5, of currents to be respectively supplied to the electrodes A 11a, 11b and the electrodes B 12a, 12b are then sent to the power supplies 6a and 6b. According to these control signals, an amount of current IA to be supplied from the power supply 6a to the electrodes A 11a, 11b, an mount of current IB to be supplied from the power supply 6b to the electrodes B 12a, 12b, and their current supplying times are controlled and currents are supplied.

Specifically, DC current with a value of IA is supplied from the power supply 6a across the electrodes A, which are the electrode A 11a disposed at the central part 101a at the concave bottom of the differential thickness member 101 and the electrode A 11b disposed on the back of the plate member 102 at the center, according to the control signal 22a from the energizing controller 5 while the differential thickness member 101 and the plate member 102 are pressed against each other by the pressing tools 2a1 and 2a2 and the pressurizing means 2b, which constitute a pressurizing mechanism.

DC current with a value of IB is also supplied from the power supply 6b across each pair of electrodes B, which are an electrode B 12a disposed on the end 101b of the differential thickness member 101 and an electrode B 12b disposed on the back on the end of the plate member 102, according to the control signal 22b from the energizing controller 5.

When currents flow across the electrodes A and across the electrodes B under pressure as described above, resistance heat is generated on the faying surfaces 3 of the differential thickness member 101 and the plate member 102 and inside the metallic material of the differential thickness member 101 and the plate member 102, which are the metallic members to be bonded. The differential thickness member 101 and the plate member 102 are then heated by the resistance heat and bonded.

As a result, the temperature gradient on the faying surfaces of the differential thickness member 101 and the plate member 102 decreases, so the entire faying surfaces of the differential thickness member 101 and the plate member 102, which are made of the metallic material SKD61, can be increased within a prescribed bonding temperature region of 950° C. to 1200° C., achieving superior electric current bonding of the differential thickness member 101 and the plate member 102.

Next, how electric current flows in the electric current bonding apparatus, shown in FIG. 1, as an embodiment of the present invention, will be described. In FIG. 1, the electrodes A comprise an electrode A 11a disposed at the thin central part 101a of the differential thickness member 101 and an electrode A 11b disposed on the back of the plate member 102 at the center.

The electrodes B comprise a plurality of electrodes B 12a disposed on the thick end 101b of the differential thickness member 101 and a plurality of electrodes B 12b disposed on the back of the end of the plate member 102.

During the heating of these electrodes by use of electric current, a process of supplying current only across the electrodes A, electrode A 11a and electrode A 11b, and a process of supplying current only across the electrodes B, a plurality of electrodes B 12a and electrodes B 12b, are repeated.

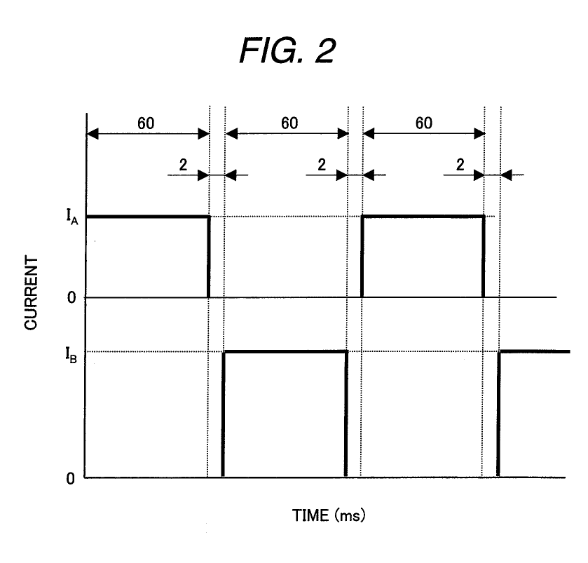

FIG. 2 is a graph representing the relationship between currents flowing across the electrodes A and across the electrodes B and time during heating by use of electric current for bonding when metallic members made of the metallic material SKD61 are bonded by the electric current bonding apparatus, shown in FIG. 1, according to the first embodiment of the present invention, by which current is supplied across the electrodes A 11a, 11b and across the electrodes B 12a, 12b disposed on the differential thickness member 101 and the plate member 102, which are the metallic members to be bonded, while the differential thickness member 101 and the plate member 102 are pressed against each other by the pressing tools 2a1 and 2a2 and the pressurizing means 2b, which constitute a pressurizing mechanism.

In this embodiment, DC current with a value of IA is supplied continuously for 60 ms to the electrode A 11a disposed at the central part 110a of the differential thickness member 101 and to the electrode A 11b disposed on the back of the plate member 102 at the center, the electrode A 11a and the electrode A 11b being paired and forming a distance between the electrodes A.

A pause of 2 ms is then provided, after which DC current with a value of IB is supplied continuously for 60 ms to the electrodes B 12a disposed on the end 101b of the differential thickness member 101 and to the electrodes B 12b disposed on the back of the end of the plate member 102, the plurality of electrodes B 12a and the plurality of electrodes B 12b being paired and forming distances among the electrodes B.

A pause of 2 ms is then provided, after which, again, DC current with a value of IA is continuously supplied across the electrodes A 11a, 11b, a pause is provided, and DC current with a value of IB is continuously supplied across the electrodes B 12a, 12b. This energizing cycle is repeated. The DC current values IA and IB to be applied across each pair of electrodes are set to values by which the differential thickness member 101 and the plate member 102, which are the metallic members to be bonded, are uniformly heated.

While the differential thickness member 101 and the plate member 102 are pressed against each other by the pressing tools 2a1 and 2a2 and the pressurizing means 2b, which constitute a pressurizing mechanism, electrode temperatures are detected as the detected temperature signals 21a and 21b by the temperature detector 4 attached to the electrode A 11b at the center of the plate member 102 and by the plurality of temperature detectors 4 attached to the plurality of electrodes B 12b on the end of the plate member 102.

The energizing controller 5 calculates amounts of electric current to be supplied from the power supply 6a and power supply 6b to the electrodes so that the detected temperature signals 21a and 21b fall within their prescribed target temperature regions. The energizing controller 5 then outputs the control signals 22a and 22b, which are used as command values to control the current value IA of the current to be supplied from the power supply 6a across the electrodes A and a time during which the current is supplied as well as the current value IB of the current to be supplied from the power supply 6b across the electrodes B and a time during which the current is supplied.

When the value of the current IA supplied across the electrodes A 11a, 11b and the value of the current IB supplied across the electrodes B 12a, 12b, as well as times taken for these electric current supplies are controlled as described above, the differential thickness member 101 and the plate member 102 to be mutually bonded, which are made of a metallic material, are heated and their temperatures are increased in such a way that the temperature gradient on the faying surfaces 3 of the metallic material decreases. Accordingly, the entire faying surfaces of the differential thickness member 101 and the plate member 102, which are made of the metallic material SDK61, can be raised within a prescribed bonding temperature region of 950° C. to 1200° C., achieving superior electric current bonding of the differential thickness member 101 and the plate member 102.

A cross sectional observation of a bond line between the differential thickness member 101 and the plate member 102 that were actually bonded shows superior bonding with no spacing across the bond line. In a tensile test conducted for a test piece sampled from the bonded metallic members, a tensile strength equivalent to the tensile strength of the parent material was obtained.

Although alloy tool steel SKD61 is used as the material of the metallic members to be bonded in this embodiment, another metallic material may be used. Three or more metallic members may be bonded and metallic members made of different materials may be bonded.

In the current supplying process in this embodiment, DC current with a fixed value is used as electric current supplied across the electrodes A 11a, 11b and across the electrodes B 12a, 12b disposed on the differential thickness member 101 and the plate member 102, which are metallic members to be bonded, but the lengths of the current supplying time and pause may be changed according to the metallic members to be bonded. In addition, alternate current, direct pulsed current, or alternate pulsed current may be used as the electric current to be supplied.

Instead of setting the energizing cycle as described above, AC current may flow across the electrodes A and across electrodes B; when the energizing controller 5 changes phases for the electrodes A and electrodes B to make a difference in current supplying timings, it is also possible to control the amounts of current supplied to the thick part and thin part of the differential thickness member 101 separately.

The pressurizing mechanism may be a hydraulic mechanism, a pneumatic mechanism, a mechanical mechanism, or another general mechanism. When the temperature detector 4 detects a temperature inside the electrode, a thermocouple or another contact temperature detector can be used as the temperature detector 4; when a temperature outside the electrode is detected, a radiation thermometer or another non-contact temperature detector can be used.

Although the differential thickness member 101 and the plate member 102 used as the metallic members to be bonded are disk, it is apparent that this embodiment is also applicable to members with any shapes, including rectangular members.

According to this embodiment, to efficiently heat and bond metallic members including parts with different thicknesses, a plurality of paired electrodes are disposed separately on the parts with the different thicknesses and current is supplied thereto. During heating, a switchover is made successively to a pair of electrodes to which to supply electric current. In addition, the electrode temperature of the pair is measured and an amount of electric current to be supplied across the electrode pair is adjusted so that the electrode temperature falls within a desired temperature region. Accordingly, the metallic members can be efficiently raised within the desired temperature region suitable for bonding, achieving uniform bonding.

### Embodiment 2

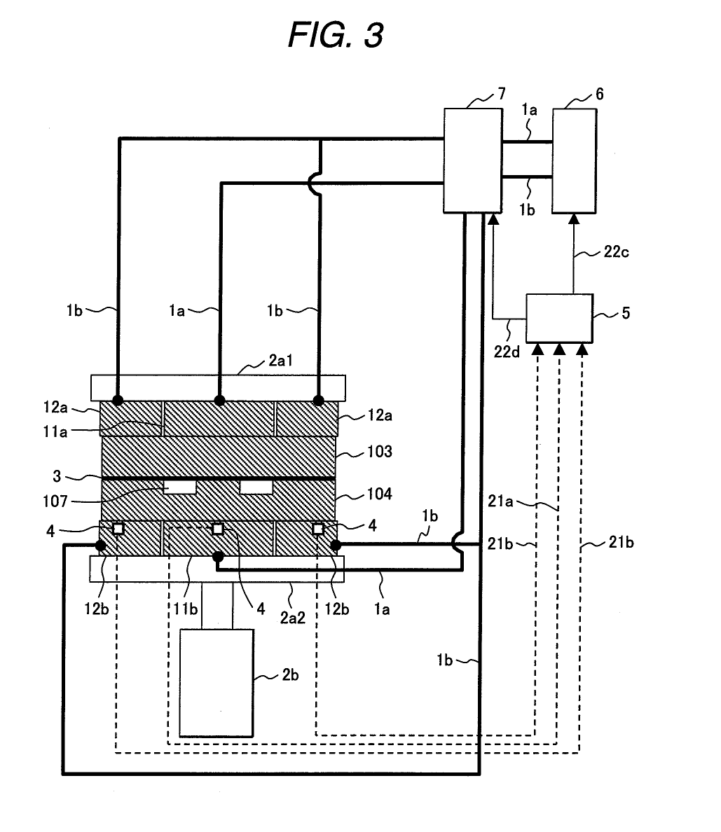

Another embodiment of an electric current bonding apparatus, second embodiment, of the present invention will be described with reference to FIG. 3. The basic structure in this embodiment shown in FIG. 3 is the same as in the first embodiment shown in FIGS. 1 and 2, so the description of the same structure will be omitted and only differences from the first embodiment will be described.

FIG. 3 shows the general structure of an electric current bonding apparatus in the second embodiment of the present invention, which includes a disk member 103, a grooved disk member 104 having grooves 107, electrodes, a power supply, a pressurizing mechanism, temperature detecting means, a current path switching mechanism, and an energizing controller, the disk member 103 and the grooved disk member 104 being used as metallic members when two metallic members are bonded. The structures of the metallic members to be bonded and electrodes are indicated as cross-sectional views.

The metallic members to be bonded in this embodiment are made of the metallic material SUS304. A metallic member disposed as the upper member of the metallic members made of the metallic material SUS304 in FIG. 3 is the disk member 103 that is uniform in thickness. The other metallic member disposed as the bottom member of the metallic members is the grooved disk member 104 that is uniform in thickness and has grooves 107 on an outer surface and is bonded to the disk member 103.

The disk member 103 and the grooved disk member 104 are disposed in such a way that faying surfaces 3, which are their opposite surfaces, are brought into contact with each other. When current is supplied by the electric current bonding apparatus under pressure, resistance heat is generated on the faying surfaces 3 of the disk members and inside the material of the disk members, thereby heating and mutually bonding the disk members.

In view of a case where a metallic member to be bonded may have grooves, the grooves 107 will be described in this embodiment by using the grooved disk member 104.

Specifically, an electrode A 11a is disposed on the disk member 103 at the center and a plurality of electrodes B 12a are disposed on the outer peripheral end. When electric current flows, a voltage is applied to the electrode A 11a disposed on the disk member 103 from a power supply 6 through an energizing path switching mechanism 7 via an energizing path 1a. A voltage is also applied to the plurality of electrodes B 12a from the power supply 6 through the energizing path switching mechanism 7 via an energizing path 1b.

An electrode A 11b is disposed on the back of the grooved disk member 104 at the center and a plurality of electrodes B 12b on the back of the outer peripheral end of the grooved disk member 104. When electric current flows, a voltage is applied to the electrode A 11b disposed on the grooved disk member 104 from the power supply 6 through an energizing path switching mechanism 7 via another energizing path 1a. A voltage is also applied to the plurality of electrodes B 12b from the power supply 6 through the energizing path switching mechanism 7 via another energizing path 1b.

The electrode A 11b disposed on the back of the grooved disk member 104 at the center and the plurality of electrodes B 12b disposed on the back of the outer peripheral end of the grooved disk member 104 are each provided with a temperature detector 4. A detected temperature signal 21a and detected temperature signals 21b, which are detected by the temperature detectors 4 from the electrode A 11b and the plurality of electrodes B 12b, respectively, are input to the energizing controller 5.

The energizing controller 5 calculates the values of currents to be respectively supplied from the power supply 6 to the electrodes A 11a, 11b and the electrodes B 12a, 12b through the energizing path switching mechanism 7 as well as their current supplying times and a command value, by which a current supply switchover is commanded for the energizing path switching mechanism 7, so that the detected temperatures each fall within a target temperature region of temperature settings, according to predetermined temperature settings necessary for electric current bonding of the metallic members to be bonded, a temperature setting being input in advance for each metallic material to be bonded, as well as the detected temperature signal 21a and detected temperature signals 21b, which are detected by the temperature detectors 4 from the electrode A 11b and the plurality of electrodes B 12b, respectively, and then input.

Pressing tools 2a1 and 2a2 as well as a pressurizing means 2b, such as a hydraulic cylinder, for applying pressing forces to these pressing tools are provided as a pressurizing mechanism for pressing the disk member 103 and grooved disk member 104, which are metallic members to be bonded, as in the first embodiment.

When the value of the current IA supplied across the electrodes A 11a, 11b and the value of the current IB supplied across the electrodes B 12a, 12b, as well as times taken for these electric current supplies are controlled, the disk member 103 and grooved disk member 104 to be mutually bonded, which are made of the metallic material SUS304, are heated and their temperatures are increased in such a way that the temperature gradient on the faying surfaces 3 of the metallic material decreases. Accordingly, the entire faying surfaces 3 of the disk member 103 and grooved disk member 104, which are made of the metallic material SUS304, can be raised within a prescribed bonding temperature region of 950° C. to 1250° C., achieving superior electric current bonding of the disk member 103 and grooved disk member 104.

Next, how electric current flows in the electric current bonding apparatus, shown in FIG. 3, as another embodiment of the present invention, will be described. In FIG. 3, the electrodes A comprise an electrode A 11a disposed at the center of the disk member 103 and an electrode A 11b disposed on the back of the grooved disk member 104 at the center; the electrodes B comprise a plurality of electrodes B 12a disposed on the outer peripheral end of the disk member 103 and a plurality of electrodes B 12b disposed on back of the outer peripheral end of the grooved disk member 104.

During the heating of these electrodes by use of electric current, a process of supplying current only across the electrodes A, forming a distance between the electrodes A 11a and 11b, and a process of supplying current only across the electrodes B, forming distances among a plurality of electrodes B 12a and 12b, are repeated.

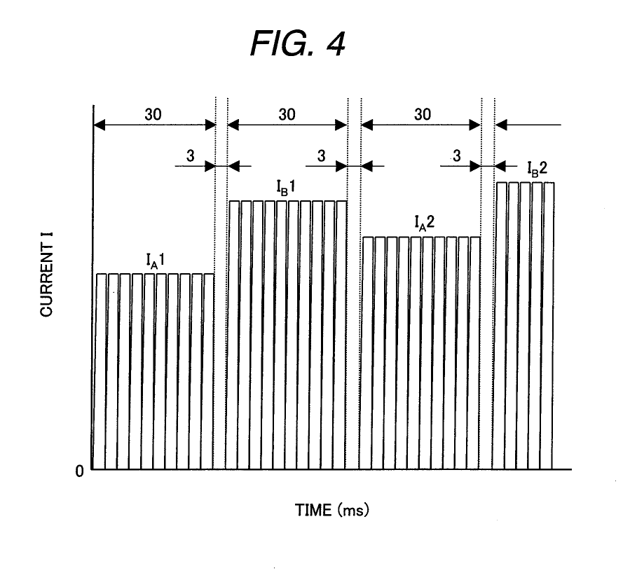

FIG. 4 is a graph representing the relationship between currents flowing across the electrodes A and across the electrodes B and time during heating by use of electric current for bonding when metallic members made of the metallic material SUS304 are bonded by the electric current bonding apparatus, shown in FIG. 3, according to the second embodiment of the present invention, by which current is supplied across the electrodes A 11a, 11b and across the electrodes B 12a, 12b disposed on the disk member 103 and grooved disk member 104, which are the metallic members to be bonded, while the disk member 103 and the grooved disk member 104 are pressed against each other by the pressing tools 2a1 and 2a2 and the pressurizing means 2b, which constitute a pressurizing mechanism.

In this embodiment, pulsed DC current with a pulse width of 3 ms and a value of IA1 is supplied for 30 ms to the electrode A 11a disposed at the center of the disk member 103 and to the electrode A 11b disposed at the center of the grooved disk member 104, which are paired and form the distance between the electrodes A, after which a pause of 3 ms is provided.

Pulsed DC current with a pulse width of 3 ms and a value of IB1 is then supplied for 30 ms to the electrodes B 12a and the electrodes B 12b, which form the distances among the electrodes B, which are pairs of the plurality of electrodes B 12a disposed on the outer peripheral end of the disk member 103 and the plurality of electrodes B 12b disposed on the outer peripheral end of the grooved disk member 104, after which a pause of 3 ms is provided.

Pulsed DC current with a pulse width of 3 ms and a value of IA2 is then supplied again for 30 ms to the electrode A 11a and the electrode A 11b, which form the distance between the electrodes A, after which a pause of 3 ms is provided.

Pulsed DC current with a pulse width of 3 ms and a value of IB2 is then supplied again for 30 ms to the electrode B 12a and the electrode B 12b, which form the distance between the electrodes B, after which a pause of 3 ms is provided.

The above energizing cycle, in which pulsed DC current with a value of IA1 or IA2 is supplied across the electrodes A, a pause is provided, and then pulsed DC current with a value of IB1 or IB2 is supplied across the electrodes B, is then repeated. One energizing cycle comprising pulsed DC current supply and a pause is counted as one unit. When a next energizing cycle starts, the current value IA1 or IA2 and its current supplying time, as well as the current value IB1 or IB2 and its current supplying time are changed, the current value representing an amount of current. For these changes to take effect, a switchover is made by the energizing path switching mechanism 7 between the energizing paths 1a and 1b.

As shown in FIG. 4, current with a value of IA (IA1 or IA2) and current with a value of IB (IB1 or IB2) are switched alternately. If the disk member 103 and grooved disk member 104, which are metallic members to be bonded, can be uniformly heated within a desired temperature region, however, either of IA1 and IA2 or either of IB1 and IB2 can be continuously supplied.

While the disk member 103 and the grooved disk member 104 are pressed against each other by the pressing tools 2a1 and 2a2 and the pressurizing means 2b, which constitute a pressurizing mechanism, the temperatures of the electrodes A and B are detected as the detected temperature signals 21a and 21b by the temperature detector 4 attached to the electrode A 11b at the center of the grooved disk member 104 and the plurality of temperature detectors 4 attached to the plurality of electrodes B 12b on the outer peripheral end of the grooved disk member 104.

The energizing controller 5 outputs the control signals 22a and 22b, which are used as command values that command amounts of current to be supplied from the power supply 6 across the electrodes A 11a, 11b and across the electrodes B 12a, 12b through the energizing path switching mechanism 7 so that the detected temperature signals 21a and 21b fall within their prescribed target temperature regions. Accordingly, the values of the electric currents IA and IB to be supplied from the power supply 6 across the electrodes A and across the electrodes B, respectively, as well as their current supply times are controlled.

When the value of the current IA supplied across the electrodes A 11a, 11b and the value of the current IB supplied across the electrodes B 12a, 12b, as well as times taken for these electric current supplies are controlled as described above, the disk member 103 and grooved disk member 104 to be mutually bonded, which are made of a metallic material, are heated and their temperatures are increased in such a way that the temperature gradient on the faying surfaces 3 of the metallic material decreases. Accordingly, the entire faying surfaces 3 of the disk member 103 and grooved disk member 104, which are made of the metallic material SUS304, can be raised within a prescribed bonding temperature region of 950° C. to 1250° C., achieving superior electric current bonding of the disk member 103 and grooved disk member 104.

A cross sectional observation of a bond line between the disk member 103 and the grooved disk member 104 that were actually bonded shows superior bonding with no spacing across the bond line. In a tensile test conducted for a test piece sampled from the bonded metallic members, a tensile strength equivalent to the tensile strength of the parent material was obtained.

Although SUS304 is used as the material of the metallic members to be bonded in this embodiment, another metallic material may be used. Three or more metallic members may be bonded and metallic members made of different materials may be bonded. In this embodiment, pulsed DC current is used in a single energizing cycle for supplying current across the electrodes A and across electrodes B, but the lengths of the current supplying time and pause may be changed according to the metallic members to be bonded. In addition, alternate pulsed current, continuous DC current, or continuous AC current may be used as the electric current to be supplied.

The pressurizing mechanism may be a hydraulic mechanism, a pneumatic mechanism, a mechanical mechanism, or another general mechanism. When the temperature detector detects a temperature inside the electrode, a thermocouple or another contact temperature detector can be used as the temperature detector; when a temperature outside the electrode is detected, a radiation thermometer or another non-contact temperature detector can be used.

Although the disk member 103 and the grooved disk member 104 used as the metallic members to be bonded are disk, it is apparent that this embodiment is also applicable to the metallic members with any shapes, including rectangular members.

According to this embodiment, to efficiently heat and bond metallic members having large faying areas to which they are mutually bonded, a plurality of paired electrodes are disposed separately at the centers and on the outer peripheries of the faying surfaces and current is supplied thereto. During heating, a switchover is made successively to a pair of electrodes to which to supply electric current. In addition, the electrode temperature of the pair is measured and the length to time to supply electric current to the electrode pair is adjusted so that the electrode temperature falls within a desired temperature region. Accordingly, the metallic members can be efficiently raised within the desired temperature region suitable for bonding, achieving uniform bonding.

### Embodiment 3

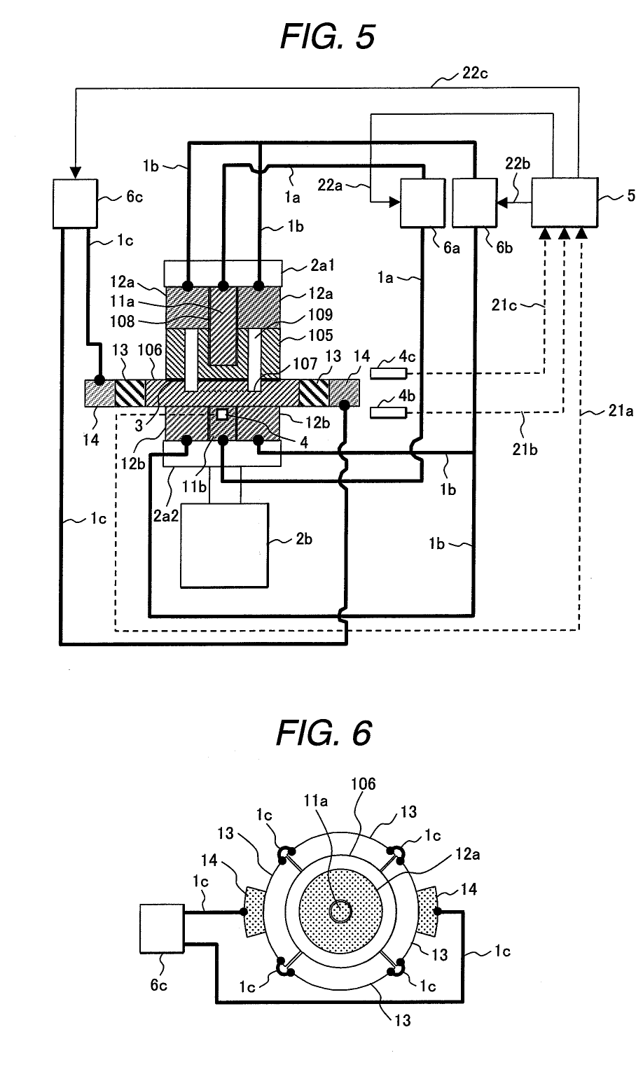

Still another embodiment of an electric current bonding apparatus, third embodiment, of the present invention will be described with reference to FIG. 5 to FIGS. 7A and 7B. The basic structure in this embodiment shown in FIG. 5 to FIGS. 7A and 7B is the same as in the first embodiment shown in FIGS. 1 and 2, so the description of the same structure will be omitted and only differences from the first embodiment will be described.

FIGS. 5 and 6 show the general structure of an electric current bonding apparatus in the third embodiment of the present invention, which includes a disk holed member 105 having holes 108 and 109, a disk chill member 106 having grooves 107, heating members, electrodes, power supplies, a pressurizing mechanism, temperature detecting means, and an energizing controller, the holed member 105 and the grooved chill member 106 being used as the metallic members when two metallic members are bonded.

FIG. 5 is a side view of the electric current bonding apparatus in the third embodiment, showing the cross sections of the metallic members to be bonded, the heating members, and the electrodes. FIG. 6 is a plan view of the electric current bonding apparatus in the third embodiment, showing the metallic members to be bonded, the heating members, and the electrodes viewed from above.

The metallic members to be bonded in this embodiment are made of an oxygen-free copper metallic material. A metallic member disposed as the upper member of the metallic members made of an oxygen-free copper metallic material in FIGS. 5 and 6 is the disk holed member 105 that is uniform in thickness and has a hole 108 at the center and a plurality of holes 109 on the periphery.

The other metallic member disposed as the bottom member of the metallic members is the grooved chill member 106 that is uniform in thickness, has grooves 107 communicating with the holes 109, and is bonded to the holed member 105.

The holed member 105 and the grooved chill member 106 are disposed in such a way that faying surfaces 3, which are their opposite surfaces, are brought into contact with each other. When current is supplied by the electric current bonding apparatus under pressure, resistance heat is generated on the contact surfaces of the metallic members to be bonded and inside the material, thereby heating and mutually bonding the metallic members to be bonded.

In view of a case where a metallic member to be bonded may have grooves and holes, the hole 108, the holes 109, and the grooves 107 will be described in this embodiment by using the holed member 105 and the grooved chill member 106.

Specifically, an electrode A 11a is disposed on the holed member 105 so that the electrode A 11a is seated in the hole 108 formed at the center of the holed member 105, and a plurality of electrodes B 12a are disposed on the outer peripheral end of the holed member 105. When electric current flows, a voltage is applied from a power supply 6a to the electrode A 11a disposed on the holed member 105 through an energizing path 1a, and a voltage is applied from a power supply 6b to each of the plurality of electrodes B 12a through an energizing path 1b.

A plurality of heating members 13, constituting a ring shape, are disposed along the radial outer periphery of the disk grooved chill member 106. Two electrodes C 14 are also attached to the radial outer peripheries of the heating members 13.

An electrode A 11b is also provided on the back of the grooved chill member 106 at the center, and a plurality of electrodes B 12b are also provided around the outer periphery of the electrode A 11b.

When electric current flows, a voltage is applied from the power supply 6a to the electrode A 11b disposed on the grooved chill member 106 through an energizing path 1a, and a voltage is applied from the power supply 6b to each of the plurality of electrodes B 12b through another energizing path 1b.

A voltage is also applied from the power supply 6c to each of the two electrodes C 14 through an energizing path 1c.

Since the grooved chill member 106 is provided with the heating members 13 and the electrodes C 14 and current supplied to the grooved chill member 106 passes through the heating members 13 and the electrodes C 14, the grooved chill member 106, which is one of the metallic members to be bonded, can be uniformly heated with higher efficiency, within a desired temperature region.

A temperature detector 4 is attached to the electrode A 11b disposed on the back of the grooved chill member 106 at the center. A non-contact temperature detector 4c for detecting the temperature of the faying surfaces 3 of the holed member 105 and grooved chill member 106 is disposed at a distance from the faying surfaces 3. A non-contact temperature detector 4b for detecting the temperature of each of the plurality of electrodes B 12b disposed along the outer periphery of grooved chill member 106 is disposed at a distance of the electrode B 12b.

The energizing controller 5 receives a detected temperature signal 21a detected from the electrode A 11b by the temperature detector 4c, a detected temperature signal 21c detected from the faying surfaces 3 of the holed member 105 and grooved chill member 106 by the temperature detector 4c, and detected temperature signals 21b detected from the plurality of electrodes B 12b by the temperature detectors 4b.

The energizing controller 5 calculates the values of the currents to be respectively supplied from the power supplies 6a, 6b, and 6c to the electrodes A 11a, 11b, the electrodes B 12a, 12b, and the electrodes C 14 as well as their current supplying times so that the detected temperatures each fall within a target temperature region of temperature settings, according to predetermined temperature settings necessary for electric current bonding of the metallic members to be bonded, a temperature setting being input in advance for each metallic material to be bonded, as well as the detected temperature signal 21a detected from the electrode A 11b by the temperature detector 4 and then input, a detected temperature signal 21c detected from the faying surfaces 3 of the holed member 105 and grooved chill member 106, and detected temperature signals 21b detected from the plurality of electrodes B 12b by the temperature detectors 4b. The amounts of current to be supplied are then commanded.

Pressing tools 2a1 and 2a2 as well as a pressurizing means 2b, such as a hydraulic cylinder, for applying pressing forces to these pressing tools are provided as a pressurizing mechanism for pressing the holed member 105 and grooved chill member 106, which are metallic members to be bonded, as in the first embodiment.

When the value of the current IA supplied across the electrodes A 11a, 11b, the value of the current IB supplied across the electrodes B 12a, 12b, and the value of the current IC supplied across the electrodes C 14, as well as times taken for these electric current supplies are controlled, the holed member 105 and grooved chill member 106 to be mutually bonded, which are made of an oxygen-free copper metallic material, are heated and their temperatures are increased in such a way that the temperature gradient on the faying surfaces 3 of the metallic material decreases. Accordingly, the entire faying surfaces 3 of the holed member 105 and grooved chill member 106, which are made of an oxygen-free copper metallic material, can be raised within a prescribed bonding temperature region of 800° C. to 950° C., achieving superior electric current bonding of the holed member 105 and grooved chill member 106.

Next, how electric current flows in the electric current bonding apparatus, shown in FIGS. 5 and 6, as another embodiment of the present invention, will be described.

In FIG. 5, the electrodes A comprise an electrode A 11a seated in the hole 108 formed at the center of the holed member 105 and an electrode A 11b disposed on the back of the grooved chill member 106 at the center; the electrodes B comprise a plurality of electrodes B 12a disposed on the outer peripheral end of the holed member 105 and a plurality of electrodes B 12b disposed on back of the outer peripheral end of the grooved chill member 106.

The electrodes C comprises two electrodes C 14 attached to the outer peripheries of the ring-shaped heating members 13 provided along the outer periphery of grooved chill member 106.

During the heating of these electrodes by use of electric current, a process of supplying current only to the electrodes A, electrode A 11a and electrode A 11b, a process of supplying current only to the electrodes B, a plurality of electrodes B 12a and electrodes B 12b, and a process of supplying current only to the electrodes C, two electrodes C 14, in each of these current supplying processes are repeated.

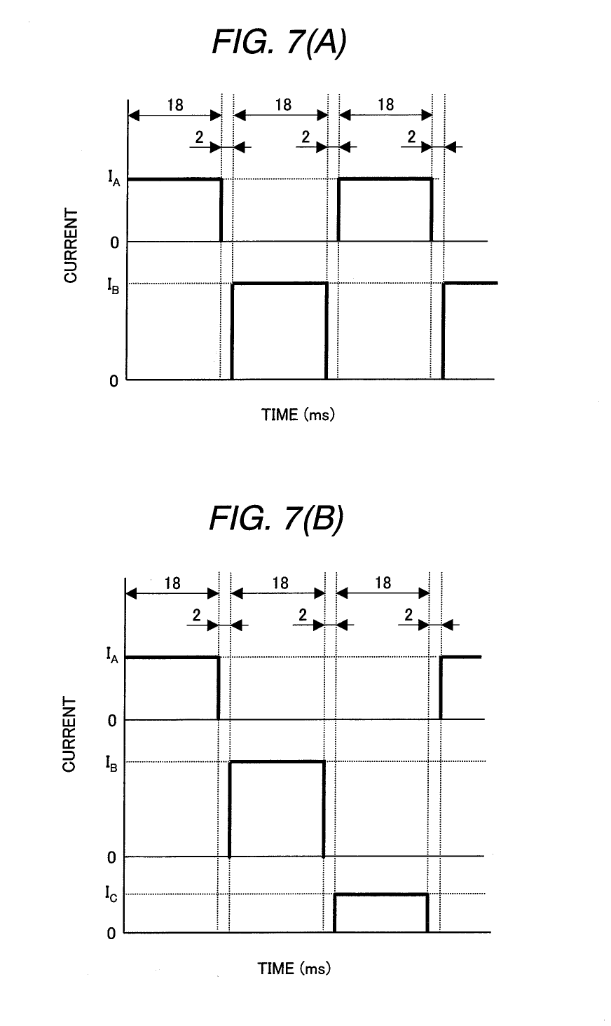

FIGS. 7A and 7B are graphs representing the relationship between currents flowing across the electrodes A, across the electrodes B, and across the electrodes C and time during heating by use of electric current for bonding when the metallic members made of an oxygen-free copper metallic material are bonded by the electric current bonding apparatus, shown in FIGS. 5 and 6, according to the third embodiment of the present invention, by which current is supplied across the electrodes A 11a, 11b and electrodes B 12a, 12b disposed on the holed member 105 and grooved chill member 106, which are the metallic members to be bonded, and if necessary across electrodes C 14 attached to the heating member 13, while the holed member 105 and the grooved chill member 106 are pressed against each other by the pressing tools 2a1 and 2a2 and the pressurizing means 2b, which constitute a pressurizing mechanism.

In this embodiment, as shown in FIG. 7A, current with a value of IA is first supplied continuously for 18 ms to the electrode A 11a disposed at the center of the holed member 105 and to the electrode A 11b disposed at the center of the grooved chill member 106, which are paired and form the distance between the electrodes A, after which a pause of 2 ms is provided.

Next, current with a value of IB is supplied continuously for 18 ms to the plurality of electrodes B 12a disposed on the outer peripheral end of the holed member 105 and to the plurality of electrodes B 12b disposed on the outer peripheral end of the grooved chill member 106, which are paired and form the distances among the electrodes B, after which a pause of 2 ms is provided.

The above energizing cycle, in which current with a value of IA is continuously supplied across the electrodes A, a pause is provided, and then current with a value of IB is continuously supplied across the electrodes B, is then repeated. One energizing cycle comprising continuous current supply and a pause is counted as one unit. When a next energizing cycle starts, the current values IA and IB, each of which represents an amount of current, are changed.

While the holed member 105 and the grooved chill member 106 are pressed against each other by the pressing tools 2a1 and 2a2 and the pressurizing means 2b, which constitute a pressurizing mechanism, the temperature of the electrodes A is detected as the detected temperature signal 21a by the temperature detector 4 attached to the electrode A 11b at the center of the grooved chill member 106.

The temperature of each electrode B 12b is also detected as the detected temperature signal 21b by the non-contact temperature detector 4b disposed at a distance from the electrodes B 12b on the outer periphery of the grooved chill member 106.

The energizing controller 5 calculates amounts of electric current to be supplied from the power supply 6a to the electrodes A 11a, 11b and from the power supply 6b to the electrodes B 12a, 12b so that the detected temperature signals 21a and 21b each fall within their prescribed target temperature region. The energizing controller 5 then outputs the control signals 22a and 22b, which are used as command values to control the current value IA of the current to be supplied from the power supply 6a to the electrodes A 11a, 11b and a time during which the current is supplied as well as the current value IB of the current to be supplied from the power supply 6b to the electrodes B 12a, 12b and a time during which the current is supplied, these currents being applied as voltages.

When the value of the current IA supplied across the electrodes A 11a, 11b and the value of the current IB supplied across the electrodes B 12a, 12b, as well as times taken for these electric current supplies are controlled as described above, the holed member 105 and grooved chill member 106 to be mutually bonded, which are made of a metallic material, are heated within a desired temperature region so that the temperature gradient on the faying surfaces 3 of the metallic material decreases.

The metallic material of the holed member 105 and grooved chill member 106 are then softened due to heating in the above heating process, and the degree of the tight contact between the holed member 105 and the grooved chill member 106 on the faying surfaces 3 is increased, reducing the amount of resistance heat generated on the faying surfaces 3. Consequently, the range of a temperature rise caused by a certain amount of increase in the currents IA and IB is reduced.

After the electric currents IA and IB have been respectively supplied across the electrodes A 11a, 11b and the electrodes B 12a, 12b, current with a value of IC is additionally supplied continuously for 18 ms to two electrodes C 14 attached to the outer peripheral end of the heating member 13, which are paired and form the distance between the electrodes C, after which a pause of 2 ms is provided, as shown in FIG. 7B. Then, each current supply is repeated.

The current value IC, which represents the value of current to be supplied from the electrodes C 14 to the heating members 13 disposed along the outer peripheral end of the grooved chill member 106, is adjusted so that the detected temperature signal 21c falls within a target bonding temperature region, the detected temperature signal 21c being regarded as a proximity temperature, measured by the temperature detector 4c, on the faying surface 3 of the holed member 105.

The current value IA of the current supplied across the electrodes A 11a, 11b and the current value of IB of the current supplied across the electrodes B 12a, 12b are continuously controlled so that the detected temperature signals 21a and 21b fall within their prescribed temperature regions, the detected temperature signal 21a being a temperature measurement obtained from the temperature detector 4 attached to the electrode A 11b, the detected temperature signal 21b being a temperature measurement obtained from the temperature detector 4b for measuring the surface temperature of the electrode B 12b.

As described above, when the value of the current IA supplied across the electrodes A 11a, 11b, the value of the current IB supplied across the electrodes B 12a, 12b, and the value of the current IC supplied across the electrodes C 14, as well as times taken for these electric current supplies are controlled, as shown in FIGS. 7A and 7B, the holed member 105 and grooved chill member 106 to be mutually bonded, which are made of a metallic material, are heated and their temperatures are increased in such a way that the temperature gradient on the faying surfaces 3 of the metallic material decreases. Accordingly, the entire faying surfaces 3 are raised within a prescribed bonding temperature region, achieving superior electric current bonding of the holed member 105 and grooved chill member 106.

When the current IC is supplied from the electrodes C 14 to the heating members 13, which have high heat generation efficiency and are disposed in the grooved chill member 106, so as to heat the heating members 13, the entire faying surfaces 3 of the holed member 105 and grooved chill member 106 are raised by heat transfer from the heating member 13 within a desired temperature region suitable for bonding. Accordingly, bonding is performed more efficiently.

As described above, when the value of the current IA supplied across the electrodes A 11a, 11b, the value of the current IB supplied across the electrodes B 12a, 12b, and the value of the current IC supplied across the electrodes C 14, as well as times taken for these electric current supplies are controlled, the holed member 105 and grooved chill member 106 to be mutually bonded, which are made of an oxygen-free copper metallic material, are heated and their temperatures are increased in such a way that the temperature gradient on the faying surfaces 3 of the metallic material decreases. Accordingly, the entire faying surfaces 3 of the holed member 105 and grooved chill member 106, which are made of an oxygen-free copper metallic material, can be raised within a prescribed bonding temperature region of 800° C. to 950° C., achieving superior electric current bonding of the holed member 105 and grooved chill member 106.

A cross sectional observation of a bond line between the holed member 105 and the grooved chill member 106 that were actually bonded shows superior bonding with no spacing across the bond line. In a tensile test conducted for a test piece sampled from the bonded metallic members, a tensile strength equivalent to the tensile strength of the parent material was obtained.

Although an oxygen-free copper metallic material is used as the material of the metallic members to be bonded in this embodiment, another metallic material, such as copper alloy or aluminum alloy may be used. Three or more metallic members may be bonded and metallic members made of different materials may be bonded.

In this embodiment, AC current with a fixed value is used in the current supplying process in which current is supplied across the electrodes A, across the electrodes B, and across the electrodes C, but the lengths of the current supplying time and pause may be changed according to the metallic members to be bonded. In addition, AC current, pulsed DC current, or pulsed AC current may be used as the electric current to be supplied.

Instead of setting the energizing cycle as shown in FIGS. 7A and 7B, AC current may flow across the electrodes; when the energizing controller 5 changes phases for the electrodes A and electrodes B to make a difference in current supplying timings, it is also possible that the energizing controller 5 controls the current IA to be supplied across the electrodes A 11a, 11b and across the electrodes B 12a, 12b to heat the holed member 105 and the grooved chill member 106, the current IB to be supplied to the outer periphery, and the current IC to be supplied across the electrodes C 14 to heat the heating members 13 separately.

Current supply to the heating members 13 disposed in the grooved chill member 106 may start when heating due to current supply starts. The pressurizing mechanism may be a hydraulic mechanism, a pneumatic mechanism, a mechanical mechanism, or another general mechanism. When the temperature detector detects a temperature inside the electrode, a thermocouple or another contact temperature detector can be used as the temperature detector; when a temperature outside the electrode is detected, a radiation thermometer or another non-contact temperature detector can be used.

In this embodiment as well, the effect as in the embodiments of the present invention described above is obtained.

Although the holed member 105 and the grooved chill member 106 used as the metallic members to be bonded are disk, it is apparent that this embodiment is also applicable to the metallic members with any shapes, including rectangular members.

According to this embodiment, to efficiently heat and bond metallic members having low electric resistance, a plurality of paired electrodes are disposed and energized; one of each electrode pair is disposed on one of the metallic members to be bonded; the other is disposed on another metallic member having high electric resistance, which is in contact with the one metallic member to be bonded. The metallic members to be bonded are heated by heat transfer of heat generated in the other metallic member having high electric resistance, so less current is used to raise the metallic members efficiently within a desired temperature region suitable for bonding than when only the metallic members to be bonded are energized and heated. As a result, uniform bonding is possible.

The present invention is applicable to electric current bonding apparatuses and electric current bonding methods by which metallic materials with poor weldability and dissimilar metals are bonded in various industrial fields.

What is claimed is:

1. An electric current bonding method comprising steps of; applying external pressing forces to a plurality of metallic members through which electric current is capable of flowing so as to press the metallic members against each other, supplying electric current across the plurality of metallic members under the pressure, and heating and bonding the metallic members by use of resistance heat generated by the current supply, wherein:
disposing a plurality of paired electrodes to supply electric current between the plurality of metallic members; and
selecting an electrode pair to supply electric current from among the plurality of paired electrodes and supplying the electric current across the selected electrode pair so that the plurality of metallic members are heated within a desired temperature region and bonded.

2. An electric current bonding method according to claim 1, wherein at least either of the value of the electric current supplied across the plurality of electrodes and a time during the electric current is supplied is changed.

3. An electric current bonding method according to claim 1, wherein when electric current is supplied to the plurality of electrodes, metallic member temperatures or electrode temperatures are detected at a plurality of places and at least either of the value of the electric current supplied across the selected electrode pair and a time during the electric current is supplied is changed.

4. An electric current bonding method according to claim 1, wherein:
a heating member with another electrode is attached to one of the metallic members to be bonded;
electric current is supplied to the other electrode so as to heat the heating member; and
the metallic members to be bonded are heated by heat transfer from the heated heating member.

5. An electric current bonding apparatus, comprising:
a plurality of metallic members through which electric current is capable of flowing;
a pressurizing unit for applying pressing forces to the plurality of metallic members so as to press the metallic members against each other;
a plurality of paired electrodes disposed on the plurality of metallic members to heat the metallic members by use of resistance heat generated by a flow of electric current;
a power supply for supplying electric current to the plurality of paired electrodes; and
an energizing controller for supplying electric current from the power supply to the plurality of electrodes by making a switchover to an electrode pair to supply the electric current.

6. An electric current bonding apparatus, comprising:
a plurality of metallic members through which electric current is capable of flowing,
a pressurizing unit for applying pressing forces to the plurality of metallic members so as to press the metallic members against each other;
a plurality of paired electrodes disposed on the plurality of metallic members to heat the metallic members by use of resistance heat generated by a flow of electric current;
a plurality of power supplies for supplying electric current to the plurality of paired electrodes through a plurality of energizing paths;
an energizing switching unit for making a switchover among the plurality of energizing paths through which electric current is supplied to the plurality of paired electrodes; and
an energizing controller for controlling the energizing path switchover by the energizing switching unit so that current is supplied from the power supply to the plurality of paired electrodes.

7. An electric current bonding apparatus according to claim 5, wherein:
a heating member with another electrode is attached to one of the plurality metallic members to be bonded;
electric current is supplied from the power supply to the other electrode so as to heat the heating member; and
an amount of electric current supplied to the other electrode is controlled by the energizing controller so that the metallic members to be bonded are heated by heat transfer from the heating member.

8. An electric current bonding apparatus according to claim 6, wherein:
a heating member with another electrode is attached to one of the plurality metallic members to be bonded;
electric current is supplied from the power supply to the other electrode so as to heat the heating member; and
an amount of electric current supplied to the other electrode is controlled by the energizing controller so that the metallic members to be bonded are heated by heat transfer from the heating member.

9. An electric current bonding apparatus according to claim 5, wherein:
temperature detectors for detecting metallic member temperatures or electrode temperatures are disposed at a plurality of places; and
an amount of electric current supplied to the electrodes is controlled by the energizing controller so that the temperatures detected at the plurality of places fall within desired temperature regions thereof.

10. An electric current bonding apparatus according to claim 6, wherein:
temperature detectors for detecting metallic member temperatures or electrode temperatures are disposed at a plurality of places; and
an amount of electric current supplied to the electrodes is controlled by the energizing controller so that the temperatures detected at the plurality of places fall within desired temperature regions thereof.
